(19) United States
(12) Patent Application Publication
(10) Pub. No.: US 2018/0015569 A1
(43) Pub. Date: Jan. 18, 2018

(54) CHIP AND METHOD OF MANUFACTURING CHIPS

(71) Applicant: NANYA TECHNOLOGY CORPORATION, Taoyuan City (TW)

(72) Inventor: Po-Chun LIN, Changhua County (TW)

(21) Appl. No.: 15/213,379

(22) Filed: Jul. 18, 2016

(51) Int. Cl. B23K 26/00; H01L 21/302; B23K 26/53; B23K 101/40; B23K 103/00

(52) U.S. Cl. CPC B23K 26/0057; H01L 21/302; B23K 26/53; B23K 2203/56; B23K 2201/40

(57) ABSTRACT

A method of manufacturing chips from a semiconductor wafer having a plurality of streets on a front surface of the semiconductor wafer is provided. The method includes: forming a plurality of crack stopping structures on the semiconductor wafer at locations respectively aligned with intersections of the streets; irradiating a laser beam focused inside the semiconductor wafer along the streets to induce cracks; and breaking the irradiated semiconductor wafer along the cracks to the crack stopping structures, so as to separate the irradiated semiconductor wafer into the chips.

### BACKGROUND

### Technical Field

The present disclosure relates to a chip and a method of manufacturing chips.

### Description of Related Art

In semiconductor wafer processing, integrated circuits are formed on a wafer (also referred to as a substrate) composed of silicon or other semiconductor material. In general, layers of various materials which are either semiconducting, conducting, or insulating are utilized to form the integrated circuits. These materials are doped, deposited, and etched using various well-known processes to form integrated circuits. Each wafer is processed to form a large number of individual regions containing integrated circuits known as dies.

Following the integrated circuit formation process, the wafer is “diced” to separate the individual die from one another for packaging or for use in an unpackaged form within larger circuits. The two main techniques that are used for wafer dicing are scribing and sawing. With scribing, a diamond tipped scribe is moved across the wafer surface along pre-formed scribe lines. These scribe lines extend along the spaces between the dies. These spaces are commonly referred to as “streets.” The diamond scribe forms shallow scratches in the wafer surface along the streets. Upon the application of pressure, such as with a roller, the wafer separates along the scribe lines. The breaks in the wafer follow the crystal lattice structure of the wafer substrate. Scribing can be used for wafers that are about 10 mils (thousandths of an inch) or less in thickness. For thicker wafers, sawing is presently the preferred method for dicing.

With sawing, a diamond tipped saw rotating at high revolutions per minute contacts the wafer surface and saws the wafer along the streets. The wafer is mounted on a supporting member such as an adhesive film stretched across a film frame and the saw is repeatedly applied to both the vertical and horizontal streets. One problem with either scribing or sawing is that chips and gouges can form along the severed edges of the dies. In addition, cracks can form and propagate from the edges of the dies into the substrate and render the integrated circuit inoperative. Chipping and cracking are particularly a problem with scribing because only one side of a square or rectangular die can be scribed in the direction of the crystalline structure. Consequently, cleaving of the other side of the die results in a jagged separation line. Because of chipping and cracking, additional spacing is often required between the dies on the wafer to prevent damage to the integrated circuits. Such additional spacing can keep the chips and cracks at a distance from the actual integrated circuits. As a result of the spacing requirements, not as many dies can be formed on a standard sized wafer and wafer real estate that could otherwise be used for circuitry is wasted. The use of a saw exacerbates the waste of real estate on a semiconductor wafer. The blade of a typical saw is approximately 15 μm thick. As such, to insure that cracking and other damage surrounding the cut made by the saw does not harm the integrated circuits, three to five hundred μm often must separate the circuitry of each of the dies. Furthermore, after cutting, each die requires substantial cleaning to remove particles and other contaminants that result from the sawing process.

Another dicing technique is referred to as “stealth dicing.” In stealth dicing, an infrared laser beam is focused inside a silicon substrate to generate defects or cracking. Then, the dies may be singulated by the application of tensile forces along the laser induced cracks. However, existing stealth dicing techniques may result in unwanted crack propagation and chipping.

Accordingly, how to provide a method of manufacturing chips to solve the aforementioned problems becomes an important issue to be solved by those in the industry.

### SUMMARY

An aspect of the disclosure is to provide a method of manufacturing chips that can prevent the singulated chips from unwanted crack propagation and chipping (especially at the corners of the singulated chips).

According to an embodiment of the disclosure, the method of manufacturing chips is performed on a semiconductor wafer having a front surface on which a plurality of streets are defined. The method includes: forming a plurality of crack stopping structures on the semiconductor wafer at locations respectively aligned with intersections of the streets; irradiating a laser beam focused inside the semiconductor wafer along the streets to induce cracks; and breaking the irradiated semiconductor wafer along the cracks to the crack stopping structures, so as to separate the irradiated semiconductor wafer into the chips.

In an embodiment of the disclosure, the breaking includes applying a tensile force to the irradiated semiconductor wafer.

In an embodiment of the disclosure, a protective tap is adhered to a back surface of the semiconductor wafer. The applying includes expanding the protective tap outwardly to apply the tensile force on the irradiated semiconductor wafer.

In an embodiment of the disclosure, the locations are on the front surface. The forming includes etching the semiconductor wafer from the front surface to form a plurality of recesses, in which the recesses serve as the crack stopping structures.

In an embodiment of the disclosure, the semiconductor wafer further has a back surface opposite to the front surface. The locations are on the back surface. The forming includes etching the semiconductor wafer from the back surface to form a plurality of recesses, in which the recesses serve as the crack stopping structures.

In an embodiment of the disclosure, the semiconductor wafer further has a back surface opposite to the front surface. The locations are on the front surface and the back surface. The forming includes etching the semiconductor wafer from the front surface to form a plurality of first recesses and from the back surface to form a plurality of second recesses, in which the first recesses and the second recesses serve as the crack stopping structures.

In an embodiment of the disclosure, the semiconductor wafer further has a back surface opposite to the front surface. The forming includes etching the semiconductor wafer to form a plurality of through holes through the front surface and the back surface, in which the through holes serve as the crack stopping structures.

In an embodiment of the disclosure, the semiconductor wafer further has a back surface opposite to the front surface. The irradiating further includes moving a focus point of the laser beam from the inside of the semiconductor wafer to the back surface during irradiating.

In an embodiment of the disclosure, the semiconductor wafer further has a back surface opposite to the front surface. The method further includes thinning the irradiated semiconductor wafer from the back surface to make the thinned back surface approach a focus point of the laser beam.

In an embodiment of the disclosure, the semiconductor wafer further has a back surface opposite to the front surface. A focus point of the laser beam is proximal to the back surface and distal to the front surface.

Another aspect of the disclosure is to provide a chip, in which there is no unwanted crack propagation and chipping occurred at its corners.

According to an embodiment of the disclosure, the chip includes a substrate, a device, and a plurality of crack stopping structures. The substrate has a plurality of corners. The device is disposed on the substrate. The crack stopping structures are respectively located at the corners.

In an embodiment of the disclosure, the crack stopping structures are chamfers.

In an embodiment of the disclosure, the substrate further has a front surface on which the device is disposed. Each of the chamfers is extended to the front surface.

In an embodiment of the disclosure, the substrate further has a back surface opposite to the front surface. Each of the chamfers is further extended to the back surface.

In an embodiment of the disclosure, when viewing a profile of the substrate from above, each of the chamfers has at least one straight contour line.

In an embodiment of the disclosure, the when viewing a profile of the substrate from above, each of the chamfers has a curved contour line.

In an embodiment of the disclosure, the curved contour line is a part of a circle.

In an embodiment of the disclosure, the curved contour line is substantially a quarter of the circle.

In an embodiment of the disclosure, the curved contour line is substantially concave toward a center of the substrate.

In an embodiment of the disclosure, at least one of the corners is concave.

Accordingly, the method of manufacturing chips of the disclosure is performed to form a plurality of crack stopping structures on the semiconductor wafer at locations respectively aligned with intersections of the streets (i.e., corresponding to corners of singulated chips) in advance, so that the chips can be singulated along cracks at edges of each chip induced by a laser beam to the crack stopping structures. As a result, the singulated chips can obtain a good corner quality because the crack stopping structures can effectively prevent the cracks at the edges from unwanted propagating at the corners.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flowchart of a method of manufacturing chips according to an embodiment of the disclosure;

FIG. 2 is a top view of a semiconductor wafer according to an embodiment of the disclosure;

FIG. 3 is a partial enlarged view of the semiconductor wafer in FIG. 2;

FIG. 4A is a cross-sectional view of the structure in FIG. 3 taken along line 4A-4A according to an embodiment of the disclosure;

FIG. 4B is a cross-sectional view of the structure in FIG. 3 taken along line 4B-4B according to an embodiment of the disclosure;

FIG. 4C is another cross-sectional view of the structure in FIG. 4B, in which the substrate is divided;

FIG. 5 is a cross-sectional view of the structure in FIG. 3 taken along line 4B-4B according to another embodiment of the disclosure;

FIG. 6A is a cross-sectional view of the structure in FIG. 3 taken along line 4A-4A according to another embodiment of the disclosure;

FIG. 6B is another cross-sectional view of the structure in FIG. 6A, in which the substrate is divided;

FIG. 7 is a cross-sectional view of the structure in FIG. 3 taken along line 4B-4B according to another embodiment of the disclosure;

FIG. 8 is a cross-sectional view of the structure in FIG. 3 taken along line 4B-4B according to another embodiment of the disclosure;

FIG. 9 is a cross-sectional view of the structure in FIG. 3 taken along line 4A-4A according to another embodiment of the disclosure;

FIG. 10 is a partial top view of a semiconductor wafer according to an embodiment of the disclosure;

FIG. 11 is a cross-sectional view of the structure in FIG. 10 taken along line 11-11 according to an embodiment of the disclosure;

FIG. 12A is a partial top view of a chip according to an embodiment of the disclosure;

FIG. 12B is a partial top view of a chip according to another embodiment of the disclosure;

FIG. 12C is a partial top view of a chip according to another embodiment of the disclosure; and

FIG. 13 is a cross-sectional view of the structure in FIG. 3 taken along line 4B-4B according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

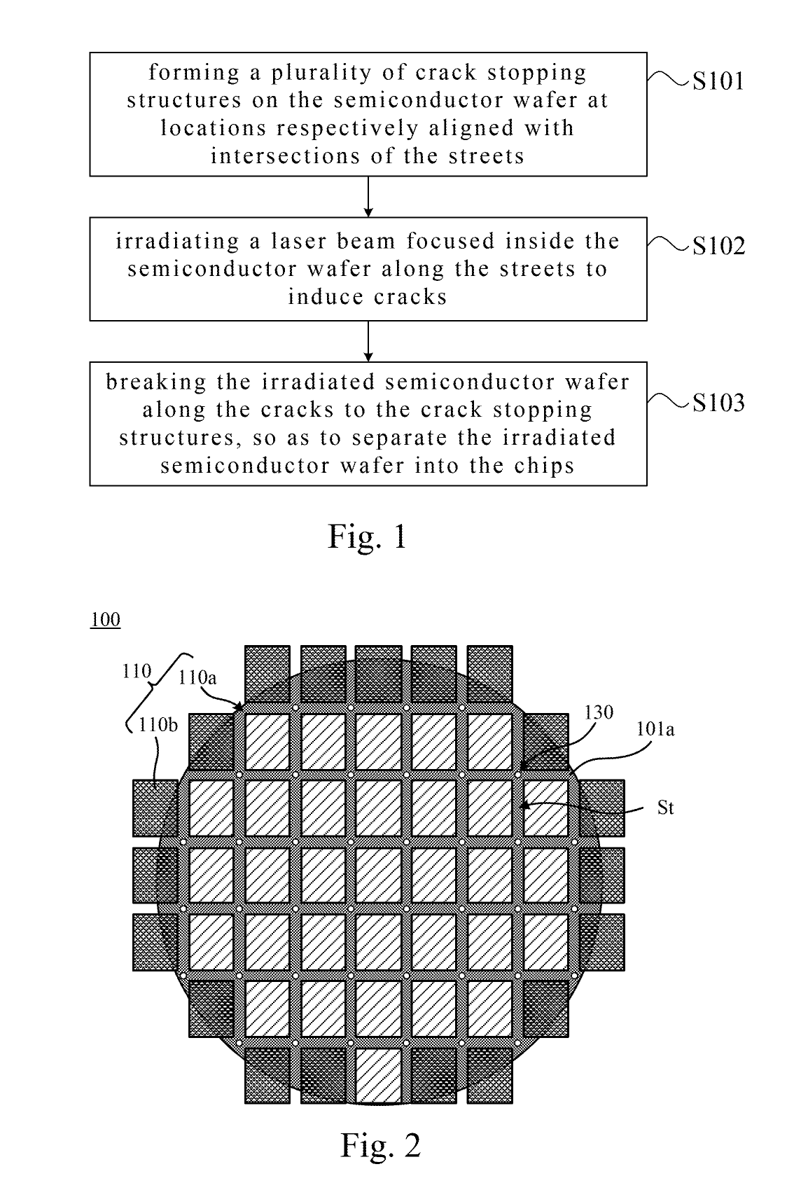

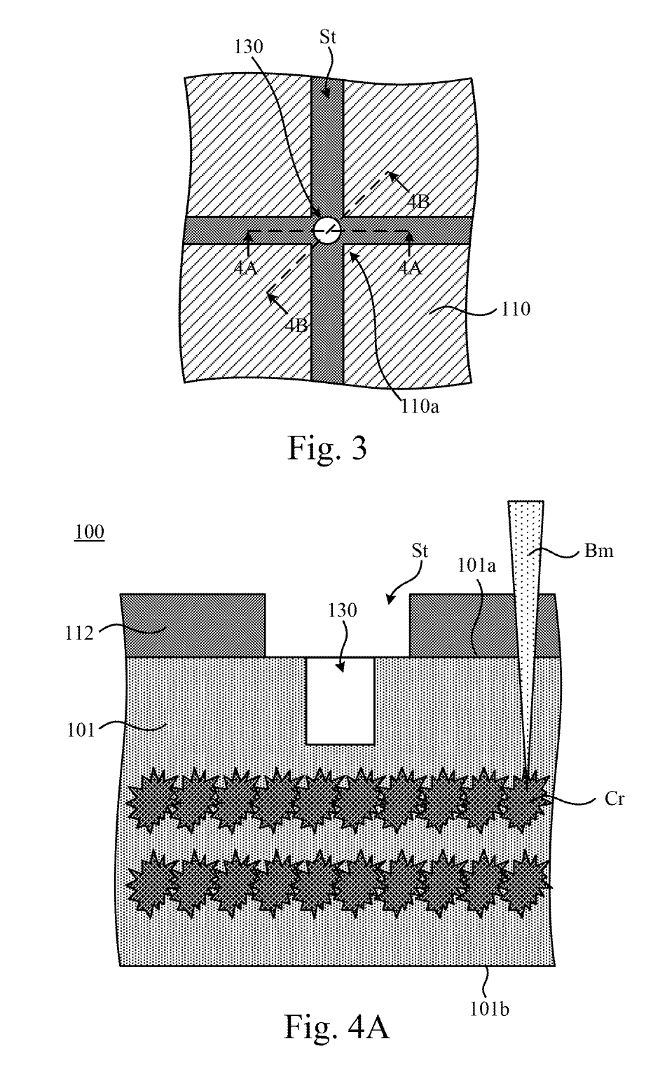

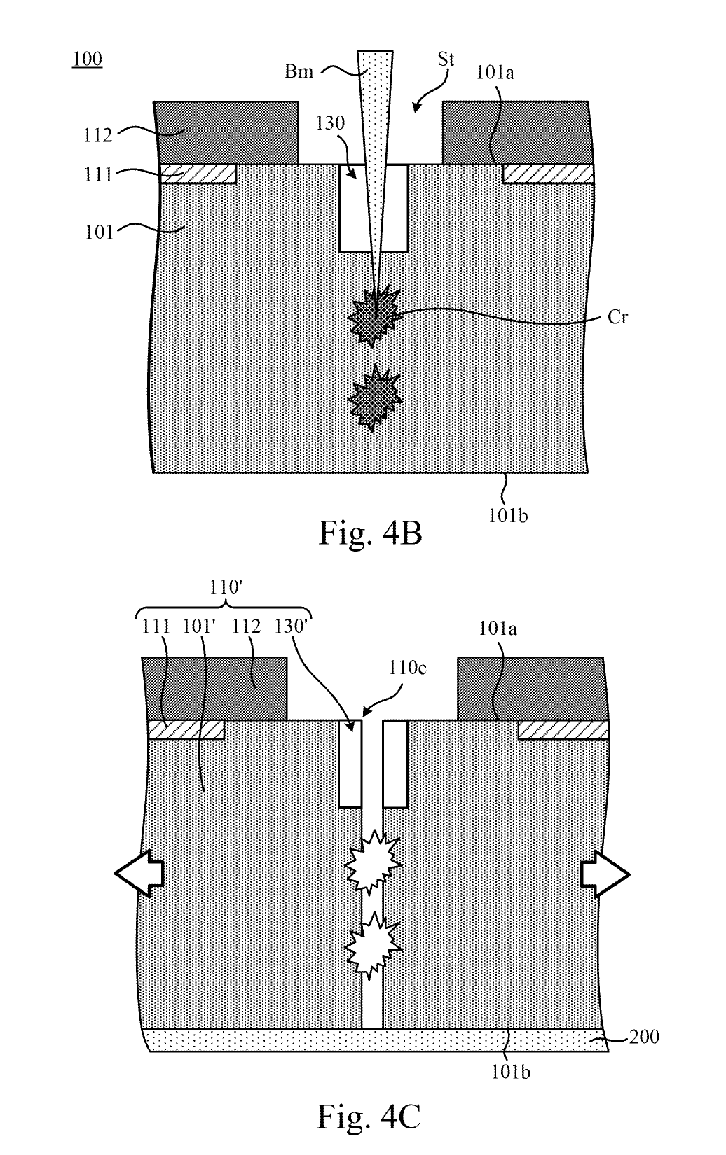

Reference is made to FIGS. 1-4C. FIG. 1 is a flowchart of a method of manufacturing chips according to an embodiment of the disclosure. FIG. 2 is a top view of a semiconductor wafer 100 according to an embodiment of the disclosure. FIG. 3 is a partial enlarged view of the semiconductor wafer 100 in FIG. 2. FIG. 4A is a cross-sectional view of the structure in FIG. 3 taken along line 4A-4A according to an embodiment of the disclosure. FIG. 4B is a cross-sectional view of the structure in FIG. 3 taken along line 4B-4B according to an embodiment of the disclosure. FIG. 4C is another cross-sectional view of the structure in FIG. 4B, in which a substrate 101′ is divided. The method of manufacturing chips of the disclosure is performed on the semiconductor wafer 100 having a front surface 101a on which a plurality of streets St are defined. The semiconductor wafer 100 further has a back surface 101b opposite to the front surface 101a.

As shown in FIG. 2, the semiconductor wafer 100 includes a plurality of dies 110 which can be classified into gross dies 110a and ink dies 110b. In general, the initial electrical performance evaluation of a die occurs after the metallization pattern process. At this stage in the chip fabrication process, a specifically configured probe station is fitted with a ring containing very fine, needle-sharp probes which are brought into physical contact with the metallized contact pads on a discrete die 110. While under computer control, the probe station automatically steps across the semiconductor wafer 100 and performs a functional electrical evaluation on each die 110. Defective dies of the dies 110 are marked with an ink spot to become the ink dies 110b, and the others of the dies 110 are the gross dies 110a. Thus, when the dies 110 are singulated from the semiconductor wafer 100, the ink dies 110b are discarded.

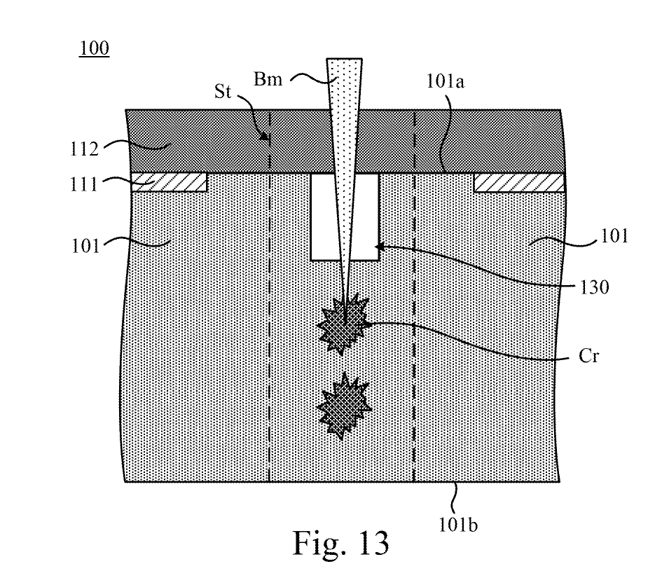

Specifically, the semiconductor wafer 100 includes a substrate 101 (e.g., a silicon substrate), a plurality of devices 111, and a plurality of dielectric layers 112. The front surface 101a and the back surface 101b are respectively located at two opposite sides of the substrate 101. The devices 111 are disposed on the front surface 101a. The dielectric layers 112 are disposed on the front surface 101a and respectively cover the devices 111. Each of the dielectric layers 112 has one or more circuits therein. In the embodiment, each of the streets St is in form of trench and formed between adjacent two of the dielectric layers 112, but the disclosure is not limited in this regard. Reference is made to FIG. 13. FIG. 13 is a cross-sectional view of the structure in FIG. 3 taken along line 4B-4B according to another embodiment of the disclosure. As shown in FIG. 13, the dielectric layers 112 covers the entire front surface 101a of the substrate 101, and each of the streets St is defined between adjacent two of dies 110 before singulated. That is, the defined streets St are separating locations of the dies 110 that are predetermined on the semiconductor wafer 100.

The method begins with operation S101 in which a plurality of crack stopping structures 130 are formed on the semiconductor wafer 100 at locations respectively aligned with intersections of the streets St (see FIGS. 2-4B). The method continues with operation S102 in which a laser beam Bm focused inside the semiconductor wafer 100 is irradiated along the streets St to induce cracks Cr (see FIGS. 4A and 4B). It should be pointed out that the internally-focused laser beam Bm induces defects inside the substrate 101. The defects may include the cracks Cr in the region in which the laser is focused, or simply a phase change such as change of the crystalline silicon substrate 101 into an amorphous silicon substrate, or the crystalline silicon substrate 101 to a liquid silicon phase. Because different phases of the same material will have different densities, a phase change is typically accompanied by a volume change in the laser-affected area. The neighboring areas that are unaffected by the laser constrain the laser-affected area and prevent or limit the volume change from occurring, which causes stress in the region of phase change and thus propagates the crack Cr in the substrate 101 of the semiconductor wafer 100. Laser induced defects may also include hole/pore formation.

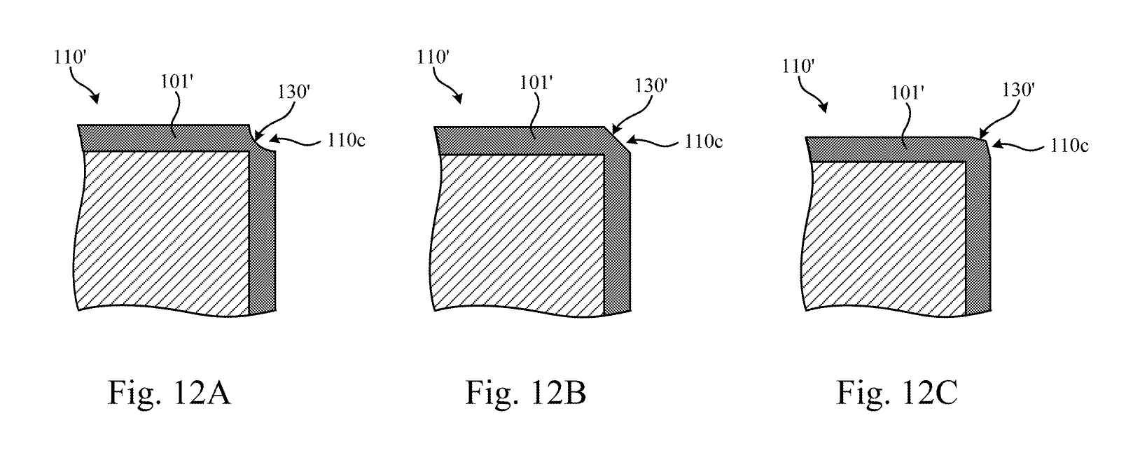

The method continues with operation S103 in which the irradiated semiconductor wafer 100 is broken along the cracks Cr to the crack stopping structures 130, so as to separate the irradiated semiconductor wafer 100 into the chips 110′ (see FIG. 4C). Each of the singulated chips 110′ includes a divided substrate 101′, the corresponding device 111 disposed on the divided substrate 101′, and the corresponding dielectric layer 112 disposed on the divided substrate 101′ and covering the device 111, and the divided crack stopping structures 130′ are respectively located at the corners 110c of the singulated chips 110′. It should be pointed out that in the singulated chip 110′, the divided crack stopping structures 130′ are in form of chamfers (e.g., see FIGS. 12A-12C).

In some embodiments, the locations of the crack stopping structures 130 are on the front surface 101a of the semiconductor wafer 100. The operation S101 includes operation S101a in which the semiconductor wafer 100 is etched from the front surface 101a to form a plurality of recesses, in which the recesses serve as the crack stopping structures 130 (see FIGS. 2-4B). That is, the crack stopping structures 130 are in form of non-through holes. It is envisaged that in the singulated chip 110′, each of the chamfers (i.e., the divided crack stopping structures 130′, see FIG. 4C) is extended to the front surface 101a.

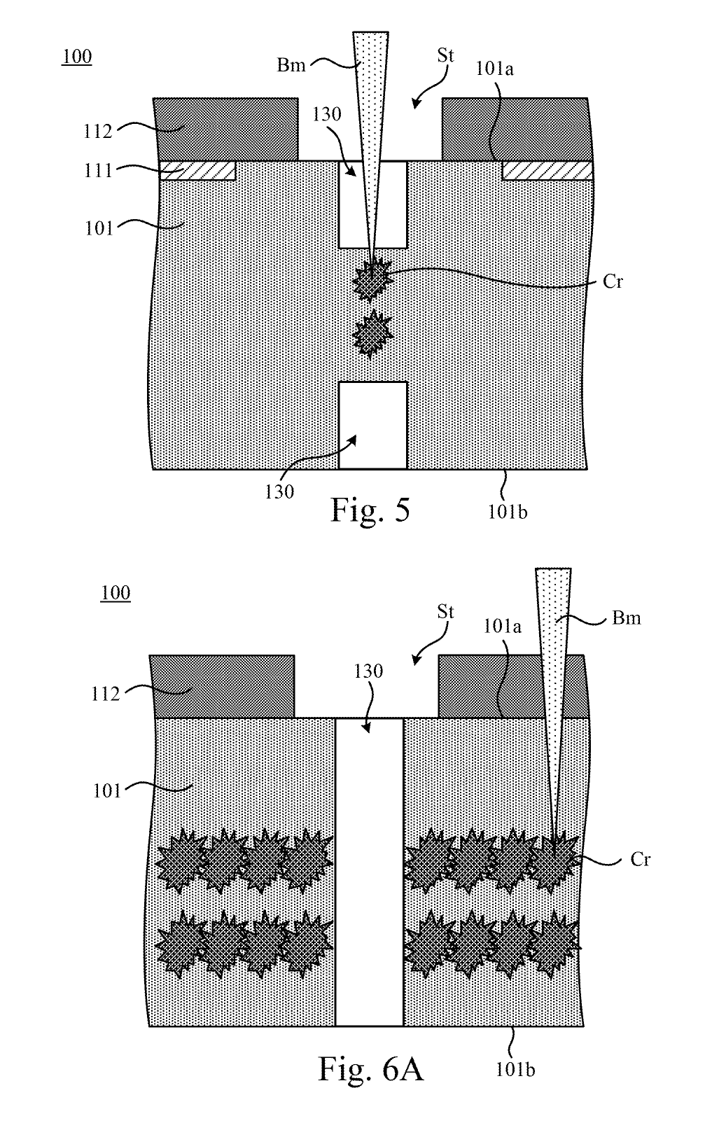

Reference is made to FIG. 5. FIG. 5 is a cross-sectional view of the structure in FIG. 3 taken along line 4B-4B according to another embodiment of the disclosure. In the embodiment, the locations of the crack stopping structures 130 are on the front surface 101a and the back surface 101b of the semiconductor wafer 100. The operation S101 includes operation S101b in which the semiconductor wafer 100 is etched from the front surface 101a to form a plurality of first recesses and from the back surface 101b to form a plurality of second recesses, in which the first recesses and the second recesses serve as the crack stopping structures 130. It is envisaged that in the singulated chip 110′, some of the chamfers (i.e., the divided crack stopping structures 130′) is extended to the front surface 101a, and the others of the chamfers is extended to the back surface 101b.

In some embodiments, the locations of the crack stopping structures 130 are on the back surface 101b of the semiconductor wafer 100. The operation S101 includes operation S101c in which the semiconductor wafer 100 is etched from the back surface 101b to form a plurality of recesses, in which the recesses serve as the crack stopping structures 130. It is envisaged that in the singulated chip 110′, each of the chamfers (i.e., the divided crack stopping structures 130′) is extended to the back surface 101b.

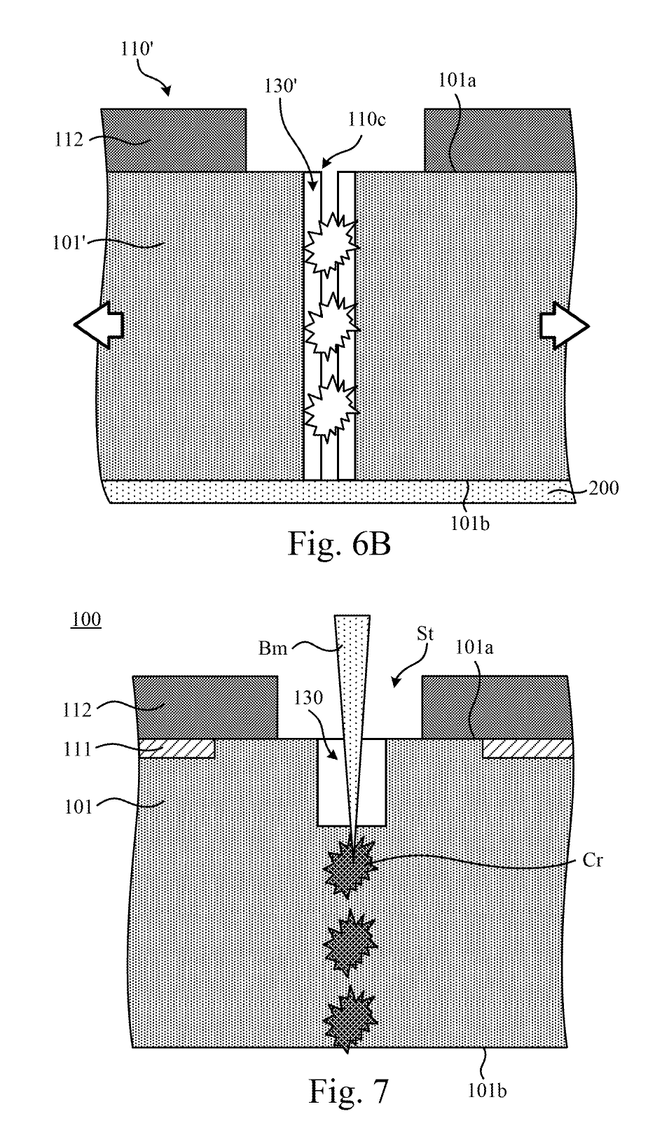

Reference is made to FIGS. 6A and 6B. FIG. 6A is a cross-sectional view of the structure in FIG. 3 taken along line 4A-4A according to another embodiment of the disclosure. FIG. 6B is another cross-sectional view of the structure in FIG. 6A, in which the substrate is divided. In the embodiment, The operation S101 includes operation S101d in which the semiconductor wafer 100 is etched to form a plurality of through holes through the front surface 101a and the back surface 101b, in which the through holes serve as the crack stopping structures 130.

In some embodiments, a focus point of the laser beam Bm is proximal to the back surface 101b and distal to the front surface 101a. In this regards, the cracks Cr induced by the damages of the laser beam Bm are proximal to the back surface 101b, which is helpful to divide the irradiated semiconductor wafer 100. It is envisaged that in the singulated chip 110′, each of the chamfers (i.e., the divided crack stopping structures 130′, see FIG. 6B) is extended to the front surface 101a and the back surface 101b.

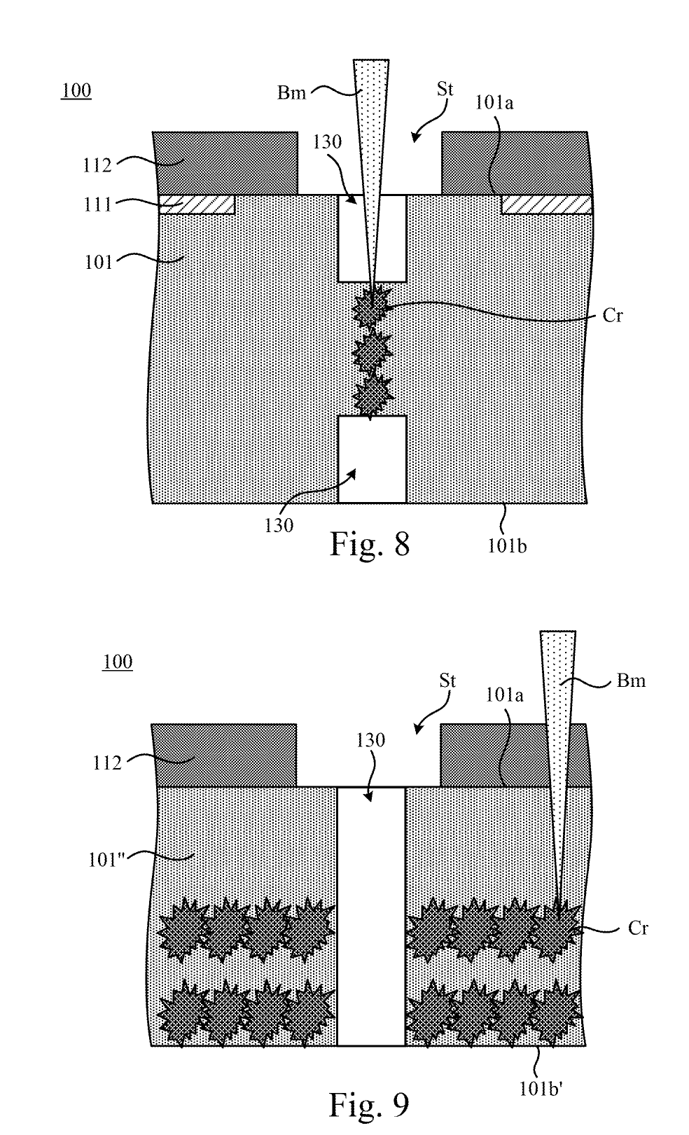

Reference is made to FIGS. 7 and 8. FIG. 7 is a cross-sectional view of the structure in FIG. 3 taken along line 4B-4B according to another embodiment of the disclosure. FIG. 8 is a cross-sectional view of the structure in FIG. 3 taken along line 4B-4B according to another embodiment of the disclosure. In the embodiments, the operation S102 includes operation S102a in which a focus point of the laser beam Bm is moved from the inside of the semiconductor wafer 100 to the back surface 101b during irradiating. In this regards, the formed cracks Cr induced by the damages of the laser beam Bm can reach the back surface 101b shown in FIG. 7 and reach the crack stopping structures 130 at the back surface 101b shown in FIG. 8, which is helpful to divide the irradiated semiconductor wafer 100.

Reference is made to FIG. 9. FIG. 9 is a cross-sectional view of the structure in FIG. 3 taken along line 4A-4A according to another embodiment of the disclosure. In the embodiment, the operation S102 includes operation S102b in which the irradiated semiconductor wafer 100 is thinned from the back surface 101b to make the thinned back surface 101b′ approach a focus point of the laser beam Bm. In this regards, the formed cracks Cr induced by the damages of the laser beam Bm can be reached by the thinned back surface 101b′ shown in FIG. 9, which is helpful to divide the irradiated semiconductor wafer 100.

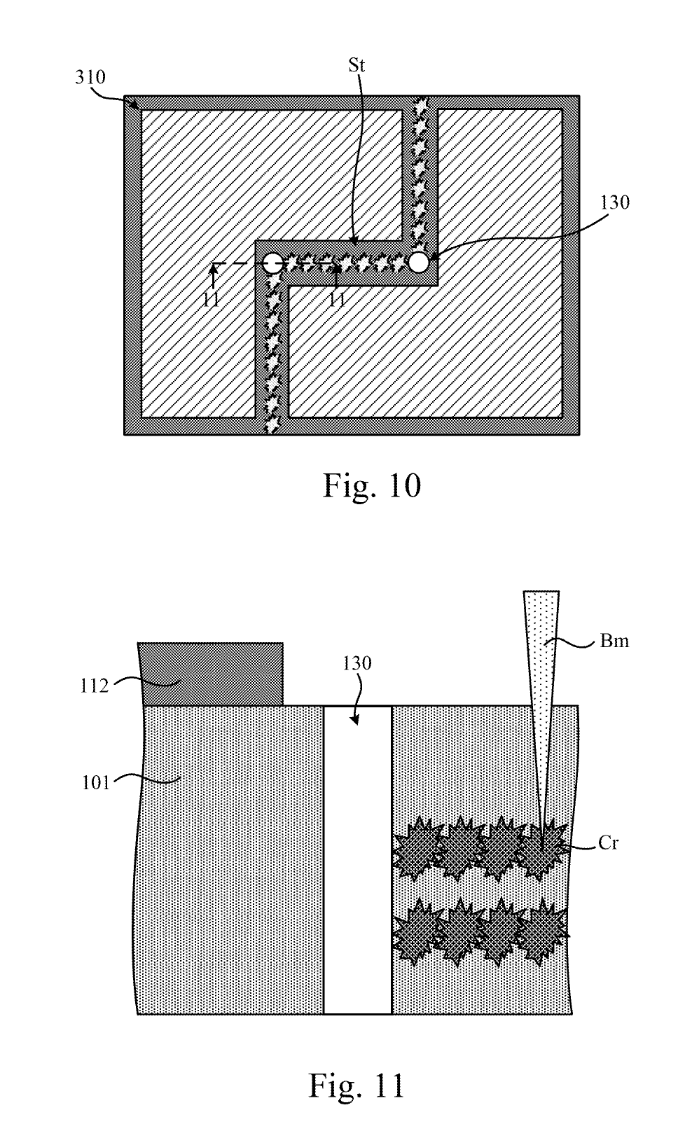

Reference is made to FIGS. 10 and 11. FIG. 10 is a partial top view of a semiconductor wafer 100 according to an embodiment of the disclosure. FIG. 11 is a cross-sectional view of the structure in FIG. 10 taken along line 11-11 according to an embodiment of the disclosure. In the embodiment, the semiconductor wafer 100 includes a plurality of chips 310 that are nonrectangular. By forming the cracks Cr induced by the damages of the laser beam Bm at a single side of the crack stopping structures 130, it is envisaged that the nonrectangular chips 310 can be obtained after singulated. In addition, as shown in FIG. 10, one of corners of the nonrectangular chips 310 is concave, and the others of the corners are convex.

In some embodiments, the operation S103 includes operation S103a in which a tensile force is applied to the irradiated semiconductor wafer 100, but the disclosure is not limited in this regard.

In some embodiments, a protective tap 200 is adhered to the back surface 101b of the semiconductor wafer 100, as shown in FIG. 4C. The operation S103a includes operation S103b in which the protective tap 200 is expanded outwardly to apply the tensile force on the irradiated semiconductor wafer 100, but the disclosure is not limited in this regard.

Reference is made to FIGS. 12A-12C. FIG. 12A is a partial top view of a chip 110′ according to an embodiment of the disclosure. FIG. 12B is a partial top view of a chip 110′ according to another embodiment of the disclosure. FIG. 12C is a partial top view of a chip 110′ according to another embodiment of the disclosure.

As shown in FIG. 12A, when viewing a profile of the substrate 101′ of the chip 110′ from above, each of the chamfers at the corresponding corner 110c has a curved contour line.

In some embodiments, the curved contour line is a part of a circle, but the disclosure is not limited in this regard.

In some embodiments, the curved contour line is substantially a quarter of the circle, but the disclosure is not limited in this regard.

In some embodiments, the curved contour line is substantially concave toward a center of the substrate, but the disclosure is not limited in this regard.

As shown in FIGS. 12B and 12C, when viewing a profile of the substrate 101′ of the chip 110′ from above, each of the chamfers at the corresponding corner 110c has at least one straight contour line. For example, a chamfer shown in FIG. 12B has a single straight contour line when viewing the profile of the substrate 101′ from above. For example, a chamfer shown in FIG. 12C has two straight contour lines when viewing the profile of the substrate 101′ from above.

According to the foregoing recitations of the embodiments of the disclosure, it can be seen that the method of manufacturing chips of the disclosure is performed to form a plurality of crack stopping structures on the semiconductor wafer at locations respectively aligned with intersections of the streets (i.e., corresponding to corners of singulated chips) in advance, so that the chips can be singulated along cracks at edges of each chip induced by a laser beam to the crack stopping structures. As a result, the singulated chips can obtain a good corner quality because the crack stopping structures can effectively prevent the cracks at the edges from unwanted propagating at the corners.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A method of manufacturing chips from a semiconductor wafer having a front surface on which a plurality of streets are defined and a back surface opposite to the front surface, the method comprising:
forming a plurality of crack stopping structures on the semiconductor wafer at locations respectively aligned with intersections of the streets, wherein the locations are on the front surface, and the forming comprises:
etching the semiconductor wafer from the front surface to form a plurality of recesses, wherein the recesses serve as the crack stopping structures;
irradiating a laser beam focused inside the semiconductor wafer along the streets to induce cracks, wherein the irradiating further comprises:
moving a focus point of the laser beam at a location in the semiconductor wafer between one of the recesses and the back surface during irradiating; and
breaking the irradiated semiconductor wafer along the cracks to the crack stopping structures, so as to separate the irradiated semiconductor wafer into the chips.

2. The method of claim 1, wherein the breaking comprises:
applying a tensile force to the irradiated semiconductor wafer.

3. The method of claim 2, wherein a protective tap is adhered to a back surface of the semiconductor wafer, and the applying comprises:
expanding the protective tap outwardly to apply the tensile force on the irradiated semiconductor wafer.

4-8. (canceled)

9. The method of claim 1, wherein the method further comprises:
thinning the irradiated semiconductor wafer from the back surface to make the thinned back surface approach a focus point of the laser beam.

10. The method of claim 1, wherein a focus point of the laser beam is proximal to the back surface and distal to the front surface.

11-20. (canceled)

21. A method of manufacturing chips from a semiconductor wafer having a front surface on which a plurality of streets are defined and a back surface opposite to the front surface, the method comprising:
forming a plurality of crack stopping structures on the semiconductor wafer at locations respectively aligned with intersections of the streets, wherein the locations are on the front surface and the back surface, and the forming comprises:
etching the semiconductor wafer from the front surface to form a plurality of first recesses and from the back surface to form a plurality of second recesses, wherein the first recesses and the second recesses serve as the crack stopping structures;
irradiating a laser beam focused inside the semiconductor wafer along the streets to induce cracks; and, wherein the irradiating further comprises:
moving a focus point of the laser beam at a location in the semiconductor wafer between one of the first recesses and a corresponding one of the second recesses; and
breaking the irradiated semiconductor wafer along the cracks to the crack stopping structures, so as to separate the irradiated semiconductor wafer into the chips.
